(19) United States
(12) Patent Application Publication
(10) Pub. No.: US 2010/0046163 A1
(43) Pub. Date: Feb. 25, 2010

(54) PORTABLE ELECTRONIC DEVICE

(76) Inventors: Ching-Hao YU, Taipei (TW); Martijn Baller, Taipei (TW); Yen-Liang Chen, Taipei (TW); Yung-Chie Huang, Taipei (TW); Meng-Hsuan Shih, Taipei (TW); Wei-Chun Chien, Taipei (TW); Chien-Hsu Hou, Taipei (TW); Chi-Chen Lin, Taipei (TW); Jia-Rong Lin, Taipei (TW); Chia-Ying Lee, Taipei (TW)

Correspondence Address: Muncy, Geissler, Olds & Lowe, PLLC, P.O. BOX 1364, FAIRFAX, VA, 22038-1364, US

(21) Appl. No.: 12/543,988

(22) Filed: Aug. 19, 2009

(30) Foreign Application Priority Data
Aug. 20, 2008 (TW) 097131767

(51) Int. Cl. H05K 7/00

(52) U.S. Cl. 361/679.55

(57) ABSTRACT

A portable electronic device includes a casing, a covering layer, and a key. The casing has an opening. The covering layer covers at least one portion of the casing and covers the opening. The key is disposed at the opening and at least one portion of the key is embedded into the opening of the casing to allow one portion of the covering layer to be sandwiched between the key and the casing.

### CROSS REFERENCE TO RELATED APPLICATIONS

This Non-provisional application claims priority under 35 U.S.C. §119(a) on Patent Application No(s). 097131767 filed in Taiwan, Republic of China on Aug. 20, 2008, the entire contents of which are hereby incorporated by reference.

### BACKGROUND OF THE INVENTION

1. Field of Invention

The invention relates to an electronic device and, more particularly, to a portable electronic device.

2. Related Art

With developments of light, slim, short, and small portable electronic devices, consumers pay more attention to functions of the portable electronic devices, and they also regard the portable electronic devices as an accessory. Therefore, a texture of the portable electronic device is one of the factors directly affecting purchase by the consumers.

An external casing of a conventional portable device such as a notebook computer is attached important to improve its tactile sensation. However, internal keyboard modules, more particularly, keys just provide a data input function and fail to show a fashion design. In addition, the conventional portable electronic device does not have other additional values and functions to increase the value of the portable electronic device.

### SUMMARY OF THE INVENTION

This invention provides a portable electronic device including a covering layer for covering a casing, thus to improve the tactile sensation of the whole portable electronic device and to increase the value of the portable electronic devices.

According to one aspect of the invention, the portable electronic device includes a casing, a covering layer, and a key. The casing has an opening. The covering layer covers at least one portion of the casing and covers the opening. The key is disposed at the opening, and at least one portion of the key is embedded into the opening of the casing to allow one portion of the covering layer to be sandwiched between the key and the casing.

In one embodiment of the invention, the covering layer may be made of cloth, leather, synthetic leather, or a combination thereof.

In one embodiment of the invention, the covering layer may include a breathable material.

In one embodiment of the invention, the covering layer may be recessed between the casing and the key.

According to the above, the portable electronic device in the invention includes a covering layer. The covering layer covers at least one portion of the casing and is sandwiched between the key and the casing. The covering layer may include a soft and a breathable materials. Thus, the covering layer seems to be recessed between the casing and the key.

These and other features, aspects, and advantages of the present invention will become better understood with regard to the following description, appended claims, and accompanying drawings.

### BRIEF DESCRIPTION OF THE DRAWINGS

FIG. 1A is a schematic diagram showing a portable electronic device according to a first embodiment of the invention;

FIG. 1B is a schematic diagram showing an internal structure of a key and a casing in FIG. 1A;

FIG. 1C is a schematic diagram showing another covering layer in FIG. 1B;

FIG. 2A is a schematic diagram showing a portable electronic device according to a second embodiment of the invention;

FIG. 2B is a schematic diagram showing an internal structure of a key and a casing in FIG. 2A; and

FIG. 2C is a schematic diagram showing another covering layer in FIG. 2B.

### DETAILED DESCRIPTION OF THE INVENTION

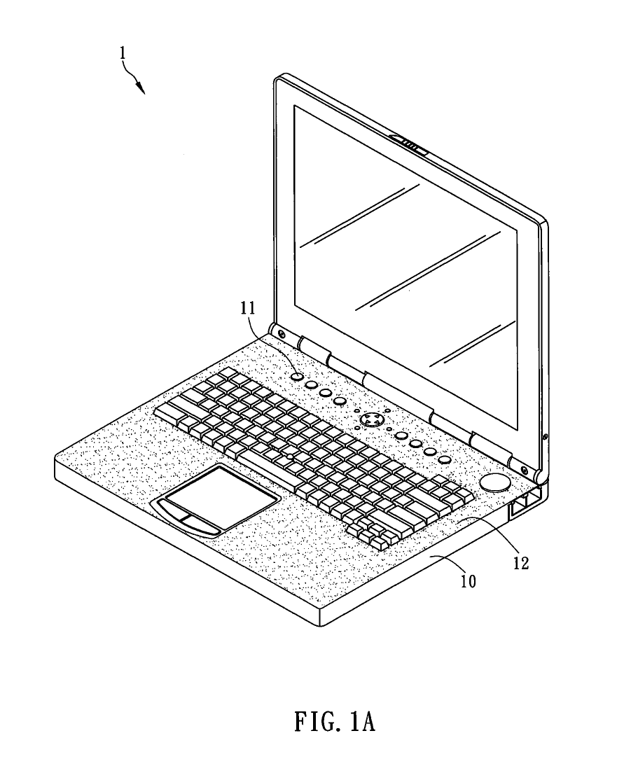

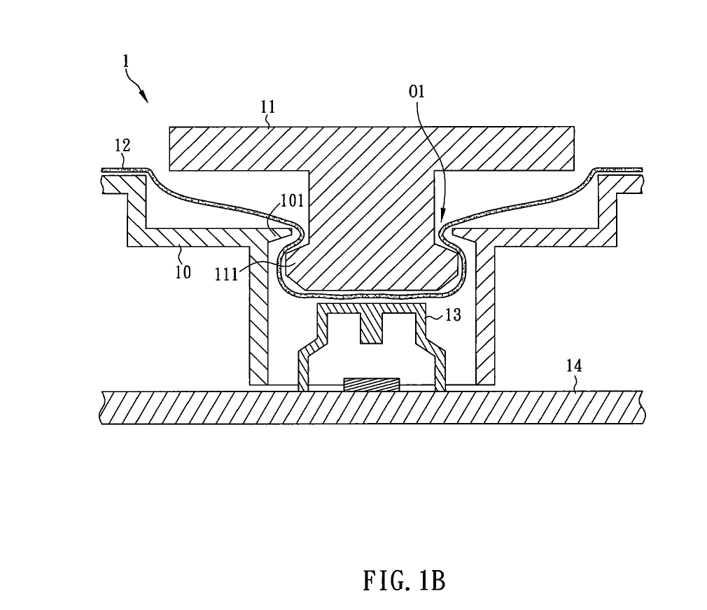

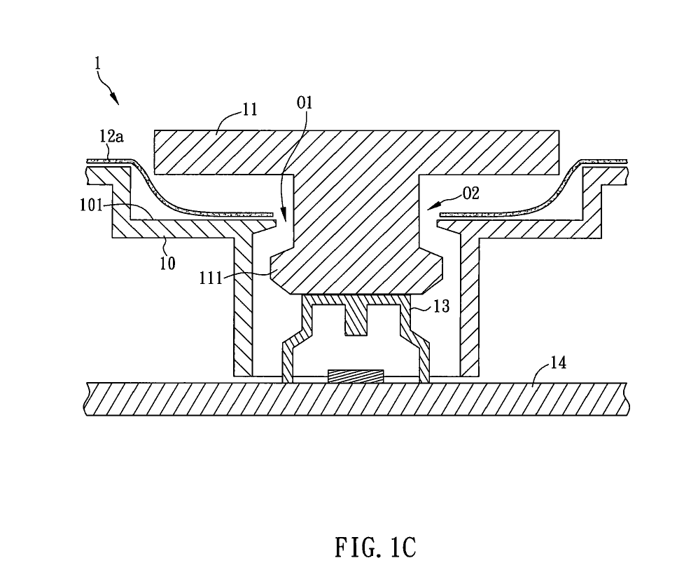

Please refer to FIG. 1A. In the first embodiment of the invention, a portable electronic device 1 includes a casing 10, a key 11, and a covering layer 12. The portable electronic device in the embodiment of the invention may be a keyboard, a notebook computer, a communication device, a media player, or other portable electronic device having the above elements. In the embodiment, a notebook computer as the portable electronic device 1 is taken for example. The casing at a keyboard side as the casing 10 is taken for example. The key 11 is disposed at the casing 10 and may be a power key. The key 11 may include other keys. The covering layer 12 covers at least one portion of the casing 10. The covering layer 12 may be made of cloth, leather, synthetic leather, or a combination thereof, such as fiber, cloth, leather, synthetic leather, rubber, silica gel and so on. The covering layer 12 may also include a breathable material.

FIG. 1B is a schematic diagram showing an internal structure of the key 11 and the casing 10 in FIG. 1A. Please refer to FIG. 1B. The casing 10 has an opening O1. The covering layer 12 covers at least one portion of the casing 10 and covers the opening O1. The key 11 is disposed at the opening O1, and at least one portion of the key 11 is embedded into the opening O1 of the casing 10 to allow one portion of the covering layer 12 to be sandwiched between the key 11 and the casing 10.

In the embodiment, the key 11 is fixedly connected to the casing 10, and the covering layer 12 is recessed between the casing 10 and the key 11. In the embodiment, the casing 10 further has a first connection portion 101, and the key 11 has a second connection portion 111 corresponding to the first connection portion 101. The first connection portion 101 and the second connection portion 111 are connected with each other. Thus, the key 11 is fixedly connected to the casing 10.

In the embodiment, the covering layer 12 is fixedly connected between the first connection portion 101 and the second connection portion 111. Thus, the covering layer 12 is fixedly connected to the casing 10. The method for fixedly connecting the covering layer 12 to the casing 10 includes the following steps. For example, the covering layer 12 is disposed on the casing 10. Then, when the key 11 is embedded into the opening O1 of the casing 10, the covering layer 12 is fixedly connected to the first connection portion 101 of the casing 10 and the second connection portion 111 of the key 12 together.

In addition, the portable electronic device 1 further includes a circuit element 14 adjacent to the key 11 and capable of generating a press signal when the key 11 is pressed. The circuit element 14 may be a circuit board or a circuit film. In addition, the portable electronic device 1 further includes an elastic element 13 disposed between the key 11 and the circuit element 14. One portion of the covering layer 12 is sandwiched between the elastic element 13 and the bottom of the key 11.

In the embodiment, the covering layer 12 can have different forms. Please refer to FIG. 1C. A covering layer 12a has a hole O2 located at the opening O1 of the casing 10. Thereby, the covering layer 12a can be recessed between the casing 10 and the key 11, thus to show a texture of a fashion design of the portable electronic device 1 and to achieve a function for absorbing perspiration and liquid inadvertently falling. In the embodiment, the key 11 passes through the hole O2 of the covering layer 12a to contact the elastic element 13 thus to allow a press signal to be generated.

Particularly, the covering layers 12, 12a may be replaceable. For example, the covering layer may include Velcro to allow the covering layers 12, 12a to be detached from and fixed to the casing 10. Thereby, when the covering layers 12, 12a are polluted by perspiration, they can be replaced.

The form of the key 11 is just taken for example. The invention does not limit the form of the key. Another form of the key is taken for example hereinbelow.

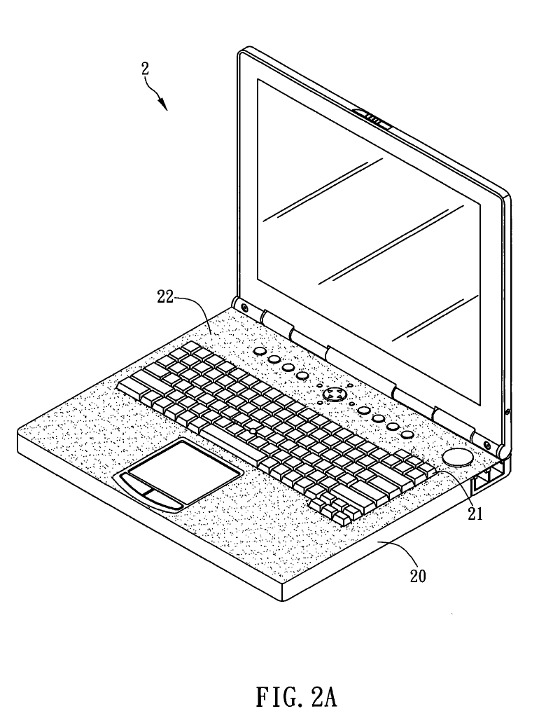

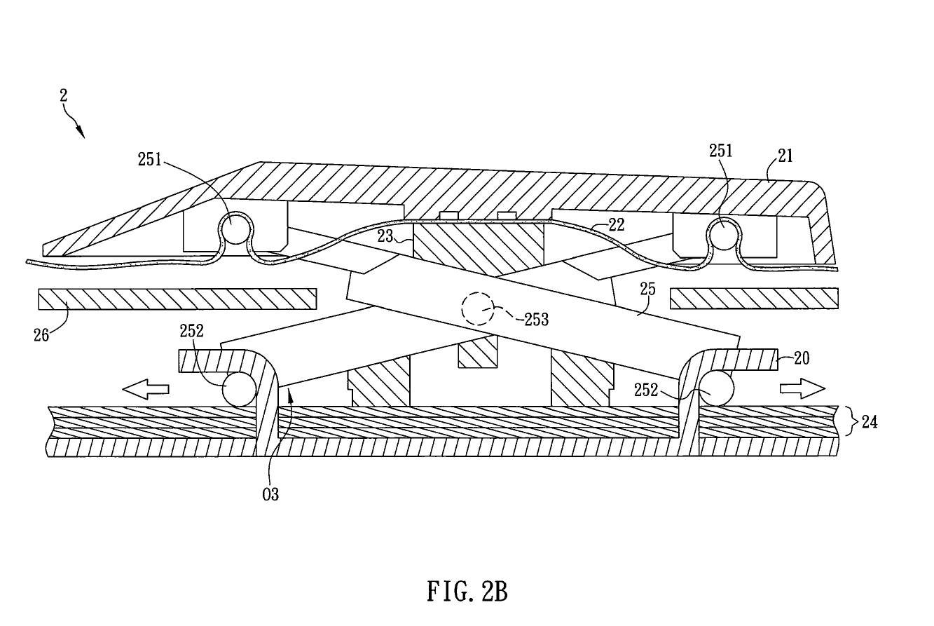

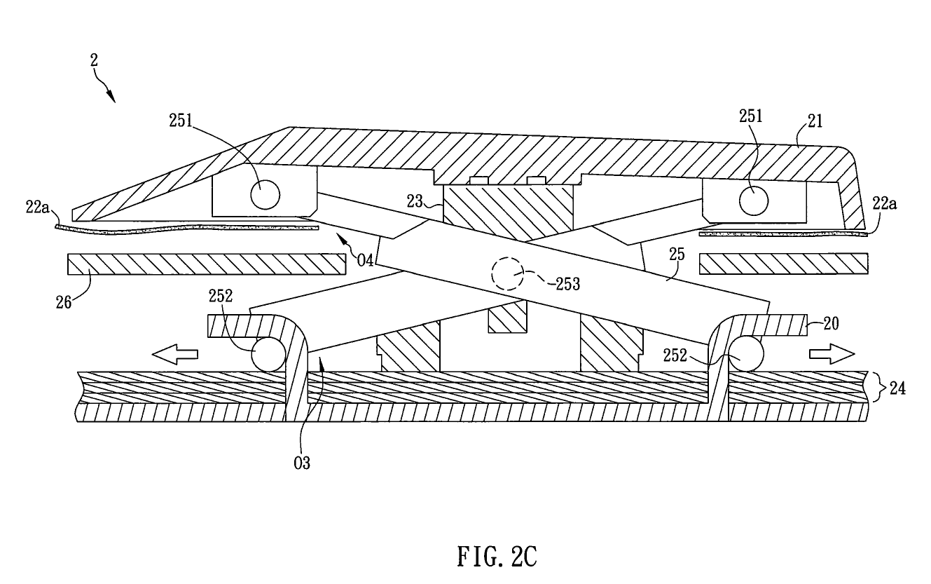

Please refer to FIG. 2A. In the second embodiment of the invention, a notebook computer as a portable electronic device 2 is taken for example. In the embodiment, the portable electronic device 2 includes a casing 20, a key 21, and a covering layer 22. The key 21 is disposed at the casing 20. A data input key as the key 21 is taken for example. FIG. 2B is a schematic diagram showing an internal structure of the key 21 and the casing 20 in FIG. 2A. The casing 20 has an opening O3. The covering layer 22 covers at least one portion of the casing 20 and covers the opening O3. The key 21 is disposed at the opening O3, and at least one portion of the key 21 is embedded into the opening O3 of the casing 20 to allow one portion of the covering layer 22 to be sandwiched between the key 21 and the casing 20.

In detail, the portable electronic device 2 further includes a bracket 25 fixedly connected to the casing 20 and the key 21, such that the covering layer 22 is fixedly connected to the key 21 and the bracket 25. The bracket 25 has a fixed portion 251, a sliding portion 252, and a hinge 253. The sliding portion 252 is slidingly disposed at the casing 20. The hinge 253 is pivotally connected to an intersection of the bracket 25. The covering layer 22 is fixedly connected between the key 21 and the fixed portion 251. The method for assembling the elements includes the following steps. For example, first, the bracket 25 is disposed at the casing 20. Then, the covering layer 22 is disposed at the casing 20. Next, when the key 21 is embedded into the casing 20, the covering layer 22 is fixedly connected to the fixed portion 251.

In addition, the portable electronic device 2 further includes a circuit element 24 adjacent to the key 21. The circuit element 24 may be a circuit board or a circuit film. In addition, the portable electronic device 2 further includes an elastic element 23. The elastic element 23 is disposed between the key 21 and the circuit element 24, and the covering layer 22 is sandwiched between the key 21 and the elastic element 23. When the key 21 is pressed, the bracket 25 slides relative to the casing 20 (shown as the arrow in FIG. 2B) via the sliding portion 252, such that the key 21 presses the elastic element 23 to contact the circuit element 24 thus to allow a press signal to be generated.

The portable electronic device 2 further includes a light-guiding element 26 disposed in the casing 20 and around the key 21. Light emitted by a light source (not shown) forms circular output light via the light-guiding element 26, such that the key 21 and the covering layer 22 can present a better visual effect.

In the embodiment, the covering layer 22 can have different forms. Please refer to FIG. 2C. A covering layer 22a has a hole O4 located at the opening O3 of the casing 20. Thereby, the covering layer 22a can be recessed between the casing 20 and the key 21, thus to show a texture of a fashion design of the portable electronic device 2 and to achieve a function for absorbing perspiration and liquid inadvertently falling. In the embodiment, the key 21 passes through the hole O4 of the covering layer 22a to contact the elastic element 23 thus to allow a press signal to be generated.

To sum up, the portable electronic device in the embodiment of the invention includes a covering layer. The covering layer covers at least one portion of the casing and is sandwiched between the key and the casing. The covering layer may include a soft and a breathable materials. Thereby, the covering layer seems to be recessed between the casing and the key, thus to improve a texture of a fashion design of the portable electronic device and to achieve other functions such as dust prevention and absorption of perspiration and so on.

Although the present invention has been described in considerable detail with reference to certain preferred embodiments thereof, the disclosure is not for limiting the scope of the invention. Persons having ordinary skill in the art may make various modifications and changes without departing from the scope and spirit of the invention. Therefore, the scope of the appended claims should not be limited to the description of the preferred embodiments described above.

What is claimed is:

1. A portable electronic device comprising:
a casing having an opening;
a covering layer covering at least one portion of the casing and covering the opening; and
a key disposed at the opening, at least one portion of the key embedded into the opening of the casing to allow one portion of the covering layer to be sandwiched between the key and the casing.

2. The portable electronic device according to claim 1, wherein the covering layer is made of cloth, leather, synthetic leather, or a combination thereof.

3. The portable electronic device according to claim 1, wherein the covering layer includes a breathable material.

4. The portable electronic device according to claim 1, wherein the covering layer has a hole located at the opening.

5. The portable electronic device according to claim 1, wherein the covering layer is recessed between the casing and the key.

6. The portable electronic device according to claim 1, wherein the covering layer is fixedly connected to the casing.

7. The portable electronic device according to claim 1, wherein the covering layer is fixedly connected to the key.

8. The portable electronic device according to claim 1, wherein the key is fixedly connected to the casing.

9. The portable electronic device according to claim 1, further comprising:
a bracket fixedly connected to the casing and the key.

10. The portable electronic device according to claim 9, wherein the covering layer is fixedly connected to the bracket and the key.

11. The portable electronic device according to claim 1, further comprising:
a circuit element adjacent to the key and generating a press signal when the key is pressed.

12. The portable electronic device according to claim 11, further comprising:
an elastic element disposed between the key and the circuit element.

13. The portable electronic device according to claim 1, further comprising:
a light-guiding element disposed in the casing and around the key.

14. The portable electronic device according to claim 1, wherein the portable electronic device is a keyboard, a notebook computer, a communication device, or a media player.
